(19) United States
(12) Patent Application Publication
(10) Pub. No.: US 2026/0033208 A1
(43) Pub. Date: Jan. 29, 2026

(54) DISPLAY DEVICE HAVING A COLOR FILTER LAYER AND A BLACK MATRIX

(71) Applicant: TOPPAN HOLDINGS INC., Tokyo (JP)

(72) Inventor: Yuki HIROTA, Taito-ku (JP)

(73) Assignee: TOPPAN HOLDINGS INC., Tokyo (JP)

(21) Appl. No.: 19/341,824

(22) Filed: Sep. 26, 2025

Related U.S. Application Data
(63) Continuation of application No. PCT/JP2024/003923, filed on Feb. 6, 2024.

(30) Foreign Application Priority Data
Mar. 27, 2023 (JP) 2023-050342

(51) Int. Cl. H10K 59/38; H10K 59/80

(52) U.S. Cl. CPC H10K 59/38; H10K 59/879; H10K 59/8792

(57) ABSTRACT

A display device and method of manufacture of a display device having good viewing angle characteristics. The device includes a substrate, a plurality of light-emitting elements that are provided on the substrate, a color filter layer that is provided on the plurality of light-emitting elements and includes a plurality of colored portions facing the respective plurality of light-emitting elements, and a black matrix that includes a plurality of partition portions each of which is sandwiched between adjacent ones of the plurality of colored portions. A height of a top surface of the black matrix is equal to or greater than a height of a top surface of the color filter layer.

### CROSS-REFERENCE TO RELATED APPLICATIONS

The present application is a continuation of and claims the benefit of priority to International Application No. PCT/JP2024/003923, filed Feb. 6, 2024, which is based upon and claims the benefit of priority to Japanese Application No. 2023-050342, filed Mar. 27, 2023. The entire contents of these applications are incorporated herein by reference.

### BACKGROUND OF THE INVENTION

### Field of the Invention

Embodiments of the present invention relate to a display device.

### Description of Background Art

In recent years, in the field of microdisplays used for head mounted displays (HMDs) and electronic viewfinders (EVFs), the use of organic electroluminescent displays (OLEDs) is attracting attention. The pixel size of micro OLEDs used in such fields has been reduced to obtain higher resolutions, with the size of small subpixels being less than 5 μm.

The current mainstream full-color display method for micro OLEDs combines a color filter with a white backlight. However, in this method, a finer pixel size leads to a greater influence of color mixing. In color mixing, light passing through a subpixel also passes through an adjacent subpixel, resulting in lower color saturation. As a display is viewed from a direction shifted more from the front, color mixing has more influence on a reduction in color saturation. Therefore, color mixing caused by the above reason deteriorates the viewing angle characteristics of a display.

See for example JP 2012-38677 A which describes a configuration in which, instead of a black matrix made of a metal such as chromium, in a color filter, red colored portions are provided not only at the positions of red subpixels but also in the regions between adjacent subpixels and in the regions, a green colored portion or a blue colored portion is partially overlapped with each of the red colored portions. The portions of the color filter in which the colored portions are overlapped with each other constitute partition walls having an optical function similar to that of a black matrix.

See also for example JP 2014-89804 A which discloses that in the configuration disclosed in JP 2012-38677 A, light is transmitted through the partition walls and the transmitted light is visible; thus, the viewing angle characteristics are different for red, green, and blue. JP 2014-89804 A describes a configuration in which protrusions made of a resin containing no colorant or a metal such as aluminum are provided at the positions of the boundaries between subpixels on a sealing layer sealing organic electroluminescent (EL) devices and in which red colored portions, green colored portions, and blue colored portions are arranged so that the end surfaces of adjacent colored portions are in contact with each other on the upper side and face each other on the lower side with one of the protrusions interposed therebetween. The protrusions prevent color mixing. The colored portions are in contact with each other on the upper side and thus have good adhesion.

The entire contents of JP 2014-89804 A and JP 2012-38677 are incorporated herein by reference.

### SUMMARY OF THE INVENTION

In an embodiment of the present invention, there is provided a display device including: a substrate; a plurality of light-emitting elements that are provided on the substrate; a color filter layer that is provided on the plurality of light-emitting elements and includes a plurality of colored portions facing the respective plurality of light-emitting elements; and a black matrix that includes a plurality of partition portions each of which is sandwiched between adjacent ones of the plurality of colored portions, in which a height of a top surface of the black matrix is equal to or greater than a height of a top surface of the color filter layer.

In an embodiment of the present invention, there is provided the display device in which the height of the top surface of the black matrix is greater than the height of the top surface of the color filter layer.

In an embodiment of the present invention, there is provided a display device including a lens layer that is provided on the color filter layer and includes a plurality of lenses facing the respective plurality of colored portions.

In an embodiment of the present invention, there is provided a display device including a lens layer that is provided on the color filter layer and includes a plurality of lenses facing the respective plurality of colored portions, in which the height of the top surface of the black matrix is greater than the height of the top surface of the color filter layer, and the lens layer has openings at positions of the plurality of partition portions so that a top surface of each of the plurality of partition portions is at least partially exposed.

In an embodiment of the present invention, there is provided a display device in which the lens layer is made of an inorganic compound or a cured product of a non-photosensitive resin.

In an embodiment of the present invention, there is provided a display device in which each of the plurality of partition portions includes a reverse tapered portion having a reverse tapered cross section parallel to a thickness direction of the substrate and to an arrangement direction of the colored portions sandwiching the corresponding one of the plurality of partition portions.

In an embodiment of the present invention, there is provided a display device in which each of the plurality of partition portions includes a plurality of reverse tapered portions that are laminated in a thickness direction of the substrate and have a reverse tapered cross section parallel to the thickness direction and to an arrangement direction of the colored portions sandwiching the corresponding one of the plurality of partition portions.

In an embodiment of the present invention, there is provided a display device in which in each of the plurality of partition portions, a top surface of one of the plurality of reverse tapered portions located on an upper side has a smaller dimension in the arrangement direction than a top surface of one of the plurality of reverse tapered portions located on a lower side.

In an embodiment of the present invention, there is provided a display device in which the black matrix is made of a cured product of a black photosensitive resin composition.

In an embodiment of the present invention, there is provided the display device according to any of the above aspects, in which each of the plurality of light-emitting elements is an organic electroluminescent device.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic cross-sectional view of a display device according to an embodiment.

FIG. 2 is a schematic cross-sectional view of a display device according to an embodiment.

FIG. 3 is a schematic cross-sectional view of a display device according to an embodiment.

FIG. 4 is a schematic cross-sectional view of a display device according to an embodiment.

FIG. 5 is a schematic cross-sectional view of a display device according to an embodiment.

FIG. 6 is a schematic cross-sectional view of a display device according to an embodiment.

FIG. 7 is a schematic cross-sectional view of a display device according to an embodiment.

FIG. 8 is a graph showing viewing angle characteristics of display devices according to an embodiment.

### DETAILED DESCRIPTION OF THE EMBODIMENTS

Embodiments will now be described with reference to the accompanying drawings, wherein like reference numerals designate corresponding or identical elements throughout the various drawings.

The embodiments described below are merely example configurations for embodying the technical idea of the present invention, and the technical idea of the present invention is not limited to the materials, shapes, structures, or the like of the components described below. Various modifications can be made to the technical idea of the present invention within the technical scope defined by the claims.

Applicant notes that components having the same or similar functions are denoted by the same reference signs in the drawings referred to below, and redundant description is omitted. In addition, the drawings are schematic, and the relationship between dimensions in one direction and another direction, dimensions of a member and another member, and the like may be different from the actual relationship.

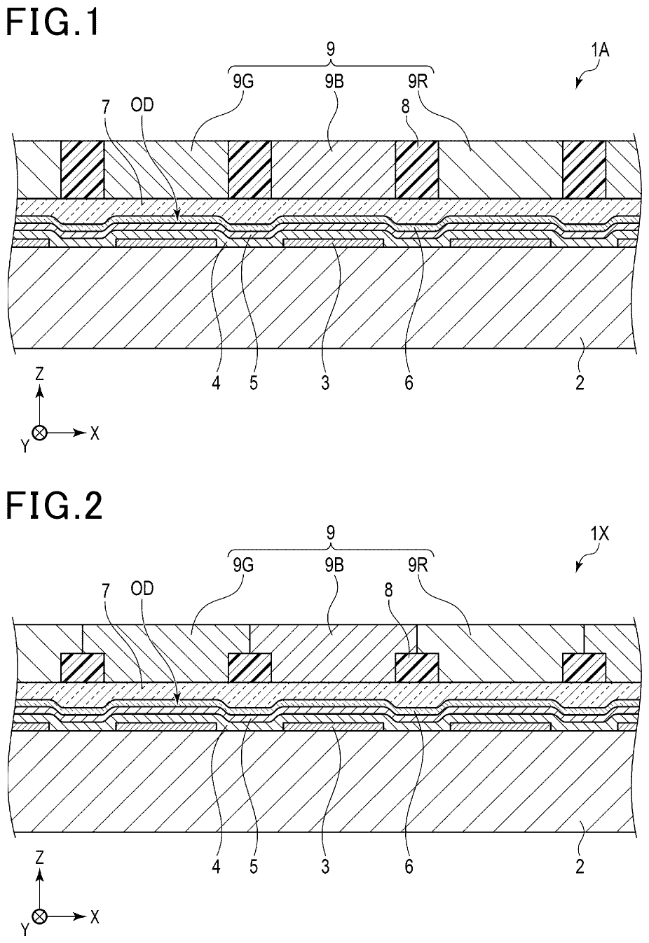

FIG. 1 is a schematic cross-sectional view of a display device according to an embodiment of the present invention. A display device 1A shown in FIG. 1 is an organic EL microdisplay. The microdisplay includes a substrate 2, anodes 3, an organic light emitting layer (organic EL layer) 4, a cathode 5, an inorganic sealing layer 6, a planarization layer 7, a black matrix 8, and a color filter layer 9.

In the figures, the X and Y directions are directions that are parallel to the top surface of the substrate 2 and intersect each other. In this example, the X and Y directions are assumed to be perpendicular to each other. The Z direction is a direction perpendicular to the X and Y directions, that is, the thickness direction of the substrate 2.

In this case, the substrate 2 is an array substrate. The array substrate includes a silicon substrate, and an array unit provided on the silicon substrate. The array unit includes pixel circuits, and a wire that supplies a signal and power to the pixel circuits. The pixel circuits each include a transistor as a drive element and a switch, a capacitor, and a wire that connects the transistor to the capacitor. The transistor may be, for example, a field-effect transistor that includes part of a surface region of the silicon substrate as a source region, a channel region, and a drain region.

The anodes 3 are arranged on the substrate 2 to correspond to the pixel circuits. In this example, the anodes 3 are assumed to be arranged in the X direction and the Y direction. The anodes 3 are pixel electrodes connected to the respective pixel circuits. For example, the anodes 3 may be made of a metal such as aluminum or an alloy.

The organic light emitting layer 4 is provided on the anodes 3. The organic light emitting layer 4 may be any layer that emits white light by charge injection.

The cathode 5 covers the organic light emitting layer 4. The cathode 5 is a common electrode connected to a feeder provided in the array unit. The anodes 3, the organic light emitting layer 4 provided on the anodes 3, and portions of the cathode 5 that face the anodes 3 with the organic light emitting layer 4 interposed therebetween constitute organic EL devices that are light-emitting elements OD.

The inorganic sealing layer 6 is provided on the cathode 5. The inorganic sealing layer 6 is provided to address a problem associated with organic EL devices generally being extremely sensitive to moisture. The inorganic sealing layer 6 may be, for example, made of an inorganic compound such as an inorganic oxide or an inorganic nitride. The inorganic sealing layer 6 may have a single-layer structure or a multilayer structure.

The planarization layer 7 is provided on the inorganic sealing layer 6. The planarization layer 7 transmits white light emitted from the organic EL devices and transmitted through the inorganic sealing layer 6. The planarization layer 7 may be, for example, made of a cured product of a resin. The resin may be, for example, an acrylic resin or an epoxy resin. The resin is preferably an acrylic resin. The planarization layer 7 may be omitted.

The color filter layer 9 is provided on the planarization layer 7. The color filter layer 9 includes first colored portions 9B, second colored portions 9G, and third colored portions 9R. For example, the first colored portions 9B, the second colored portions 9G, and the third colored portions 9R may be blue colored layers, green colored layers, and red colored layers, respectively. When white light is incident on the blue colored layers, the green colored layers, and the red colored layers, blue light, green light, and red light are transmitted through the blue colored layers, the green colored layers, and the red colored layers, respectively.

The first colored portions 9B, the second colored portions 9G, and the third colored portions 9R form a stripe arrangement. The first colored portions 9B, the second colored portions 9G, and the third colored portions 9R face the respective plurality of organic EL devices arranged in a row, with the inorganic sealing layer 6 and the planarization layer 7 interposed therebetween. The first colored portions 9B, the second colored portions 9G, and the third colored portions 9R may form a delta arrangement or a mosaic arrangement.

The first colored portions 9B, the second colored portions 9G, and the third colored portions 9R can be formed by photolithography using a colored photosensitive resin composition. The colored photosensitive resin composition may contain, for example, a pigment, a transparent resin, a photopolymerizable monomer, a photoinitiator, and a solvent.

The thickness of the color filter layer 9, that is, the thickness of the first to third colored portions, is preferably in the range of 0.2 μm to 3.0 μm, and more preferably in the range of 0.4 μm to 1.5 μm.

The dimensions of each of the first to third colored portions in the X direction and the Y direction are preferably in the range of 0.5 μm to 10.0 μm, and more preferably in the range of 1.0 μm to 5.0 μm. When a configuration of the display device 1A that is a microdisplay is applied to a larger-sized display, each of the first to third colored portions may have larger dimensions in the X direction and the Y direction.

The black matrix 8 is provided on the planarization layer 7. The black matrix 8 includes a plurality of partition portions, each of which is sandwiched between adjacent ones of the first to third colored portions. In this case, the black matrix 8 is a light shielding layer that has through holes at the positions of the first colored portion 9B, the second colored portion 9G, and the third colored portion 9R. The height of the top surface of the black matrix 8 is equal to the height of the top surface of the color filter layer 9.

The black matrix 8 may be, for example, made of a cured product of a black photosensitive resin composition. That is, the black matrix 8 can be formed by photolithography using a black photosensitive resin composition. The black photosensitive resin composition may contain, for example, a black pigment, a transparent resin, a photopolymerizable monomer, a photoinitiator, and a solvent.

In the display device 1A configured as described above, white light emitted from the organic EL devices is converted into colored light by the color filter layer 9. Thus, the display device 1A can display a color image with high color reproducibility. Furthermore, the display device 1A is suitable, for example, for use in head mounted displays and electronic viewfinders.

The display device 1A has good viewing angle characteristics as described below.

As described above, in some cases, in order to prevent color mixing, in a color filter, red colored portions are provided not only at the positions of red subpixels but also in the regions between adjacent subpixels, and in the regions, a green colored portion or a blue colored portion is partially overlapped with each of the red colored portions. The portions of the color filter in which the colored portions are overlapped with each other constitute partition walls having low visible light transmittance.

However, the partition walls do not have low transmittance in the entire visible range. Furthermore, the portions of the color filter in which the red colored portions are overlapped with the green colored portions and the portions of the color filter in which the red colored portions are overlapped with the blue colored portions have different transmission spectra. Furthermore, it is difficult for the portions of the color filter in which the colored portions are overlapped with each other to have a symmetrical cross section perpendicular to the longitudinal direction. Therefore, it is extremely difficult for this configuration to have the same viewing angle characteristics for red, green, and blue.

As described above, in some cases, protrusions made of a resin containing no colorant or a metal such as aluminum are provided at the positions of the boundaries between subpixels on a sealing layer, and red colored portions, green colored portions, and blue colored portions are arranged so that the end surfaces of adjacent colored portions are in contact with each other on the upper side and face each other on the lower side with one of the protrusions interposed therebetween. In this configuration, the protrusions prevent color mixing.

However, adjacent colored portions are in contact with each other on the upper side of the protrusions; thus, it is impossible to completely prevent light transmitted through a colored portion of a color from being incident on an adjacent colored portion of another color. Therefore, this configuration cannot sufficiently prevent color mixing.

Furthermore, when this configuration is adopted, it is necessary to form colored portions with respect to the protrusions with high positioning accuracy and to form colored portions of a color with respect to colored portions of another color with high positioning accuracy. If positional displacement of the colored portions with respect to the protrusions occurs, the configuration cannot have the same viewing angle characteristics for red, green, and blue. Furthermore, in order to form a colored portion of a color and a colored portion of another color without a gap between the colored portions, it is necessary to form colored portions so that the edge of a colored portion formed later overlaps with the edge of a colored portion formed earlier. At this time, the same structure as the partition walls is formed. Thus, in this case as well, the configuration cannot have the same viewing angle characteristics for red, green, and blue.

FIG. 2 is a schematic cross-sectional view of a display device according to a comparative example. A display device 1X shown in FIG. 2 is the same as the display device 1A described with reference to FIG. 1, except that the position of the top surface of the black matrix 8 is lower than the position of the top surface of the color filter layer 9. In the display device 1X, the black matrix 8 corresponds to the protrusions. Thus, the display device 1X cannot sufficiently prevent color mixing or have the same viewing angle characteristics for red, green, and blue.

On the other hand, in the display device 1A described with reference to FIG. 1, the first to third colored portions are separated from each other, and the partition portions of the black matrix 8 are interposed between the first to third colored portions throughout the entire thickness of the color filter layer 9. Therefore, the display device 1A can completely prevent light transmitted through a colored portion of a color from being incident on an adjacent colored portion of another color. Thus, the display device 1A can sufficiently prevent color mixing and have the same viewing angle characteristics for red, green, and blue. For these reasons, the display device 1A has good viewing angle characteristics.

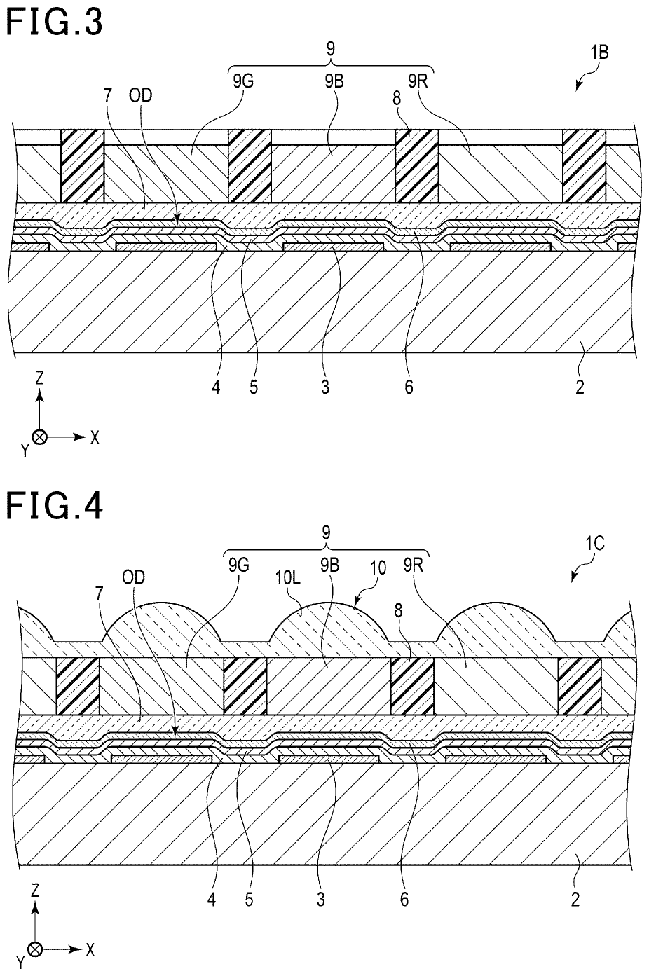

FIG. 3 is a schematic cross-sectional view of a display device according to an embodiment of the present invention. A display device 1B shown in FIG. 3 is the same as the display device 1A described with reference to FIG. 1, except that the height of the top surface of the black matrix 8 is greater than the height of the top surface of the color filter layer 9. The display device 1B has the same effects as the display device 1A.

Furthermore, as compared with the display device 1A, there is a low risk that the display device 1B has, due to production variation, a structure in which the top surface of the black matrix 8 is covered by the colored portions of the color filter layer 9, that is, the structure of the display device 1X described with reference to FIG. 2 or a similar structure. From this viewpoint, the difference between the thickness of the black matrix 8 and the thickness of the color filter layer 9 is preferably 0.05 μm or more, and more preferably 0.1 μm or more.

However, a larger difference between the thickness of the black matrix 8 and the thickness of the color filter layer 9 leads to a narrower viewing angle. Thus, the difference between the thickness of the black matrix 8 and the thickness of the color filter layer 9 is preferably 1.0 μm or less, and more preferably 0.5 μm or less.

FIG. 4 is a schematic cross-sectional view of a display device according to an embodiment of the present invention. A display device 1C shown in FIG. 4 is the same as the display device 1A described with reference to FIG. 1, except that the display device 1C further includes a lens layer 10 that is provided on the black matrix 8 and the color filter layer 9.

The lens layer 10 is a colorless and transparent layer. The lens layer 10 includes a plurality of lenses 10L that face the respective first to third colored portions. Each of the lenses 10L is a convex lens. The lenses 10L cause diffused light incident on the bottom surface of the lens layer 10 to be closer to collimated light and emerge from the top surface of the lens layer 10.

The lens layer 10 may be formed, for example, by the following method.

First, a coating film made of a photosensitive resin is formed to cover the black matrix 8 and the color filter layer 9. Next, the coating film is pattern exposed and developed to form a plurality of columnar bodies located on the respective center portions of the first to third colored portions. Then, the columnar bodies are reflow soldered, thereby obtaining the lens layer 10 including the lenses 10L.

Alternatively, first, a coating film made of a positive photosensitive resin is formed to cover the black matrix 8 and the color filter layer 9. Next, the coating film is exposed via a gray-tone mask designed so that the amount of exposure is successively increased from a portion of the coating film that corresponds to a center of each of the through holes of the black matrix 8 toward a portion of the coating film that corresponds to a side wall of the corresponding through hole, the amount of exposure being the largest at portions of the coating film that are located directly above the partition portions of the black matrix 8. Then, the coating film is developed and cured, thereby obtaining the lens layer 10 including the lenses 10L.

Alternatively, first, a negative photosensitive resin is applied onto the black matrix 8 and the color filter layer 9. The surface free energy of the black matrix 8 is assumed to be different from the surface free energy of the first to third colored portions of the color filter layer 9. Furthermore, the surface tension of the photosensitive resin is assumed to be approximately equal to the surface free energy of the first to third colored portions and significantly different from the surface free energy of the black matrix 8. In this case, the first to third colored portions are more likely to be wetted by the photosensitive resin, and the black matrix 8 is less likely to be wetted by the photosensitive resin. Therefore, island portions that are made of the photosensitive resin and have a convex curved top surface are formed on the first to third colored portions. Then, the island portions are exposed, thereby obtaining the lens layer 10 including the lenses 10L.

Alternatively, first, a transparent material layer that covers the first to third colored portions is formed. The transparent material layer may be formed to further cover the black matrix 8. Next, on the transparent material layer, a lens matrix with an island pattern corresponding to center portions of the lenses 10L is formed by photolithography and a thermal reflow process using a resist material having alkali soluble properties, photosensitivity, and thermal flow properties. Then, the shape of the lens matrix is transferred to the acrylic transparent material layer by dry etching, thereby obtaining the lens layer 10 including the lenses 10L. In this method, the transparent material layer may not necessarily be made of a photosensitive material. Therefore, for example, this method makes it possible to form a lens layer 10 made of an inorganic compound or a cured product of a non-photosensitive resin.

The display device 1C has the same effects as the display device 1A. Furthermore, as described above, the lenses 10L cause diffused light incident on the bottom surface of the lens layer 10 to be closer to collimated light and emerge from the top surface of the lens layer 10. Thus, the display device 1C is particularly suitable for uses that do not require a wide viewing angle.

FIG. 5 is a schematic cross-sectional view of a display device according to an embodiment of the present invention. A display device 1D shown in FIG. 5 is the same as the display device 1B described with reference to FIG. 3, except that the display device 1D further includes the lens layer 10 provided on the black matrix 8 and the color filter layer 9. Furthermore, the lens layer 10 of the display device ID is the same as the lens layer 10 of the display device 1C described with reference to FIG. 4, except that the lens layer 10 of the display device 1D has openings at the positions of the partition portions of the black matrix 8 so that the top surface of each of the partition portions is at least partially exposed.

The display device 1D has the same effects as the display device 1B. Furthermore, as described above, the lenses 10L cause diffused light incident on the bottom surface of the lens layer 10 to be closer to collimated light and emerge from the top surface of the lens layer 10. Thus, the display device 1D is particularly suitable for uses that do not require a wide viewing angle.

In the display device ID, as described above, the lens layer 10 has the openings at the positions of the partition portions of the black matrix 8 so that the top surface of each of the partition portions is at least partially exposed. When this configuration is adopted, it is possible to more reliably prevent colored light emerging from a subpixel, from being incident on the lens 10L of an adjacent subpixel. Exposure of the top surfaces of the partition portions leads to less reflection of external light. Furthermore, the partition portions are projected upward from the top surface of the color filter layer 9; thus, when the method in which the lenses 10L are formed by side etching is adopted, there is a low risk that the color filter layer 9 would be damaged by excessive etching. Also from this viewpoint, the difference between the thickness of the black matrix 8 and the thickness of the color filter layer 9 is preferably in the range described above for the display device 1B.

In the display device ID, the lens layer 10 may be provided to cover the entire top surface of each of the partition portions of the black matrix 8. In this case, the display device ID cannot have the aforementioned effects of the structure in which the top surface of each of the partition portions is exposed, but can have other effects.

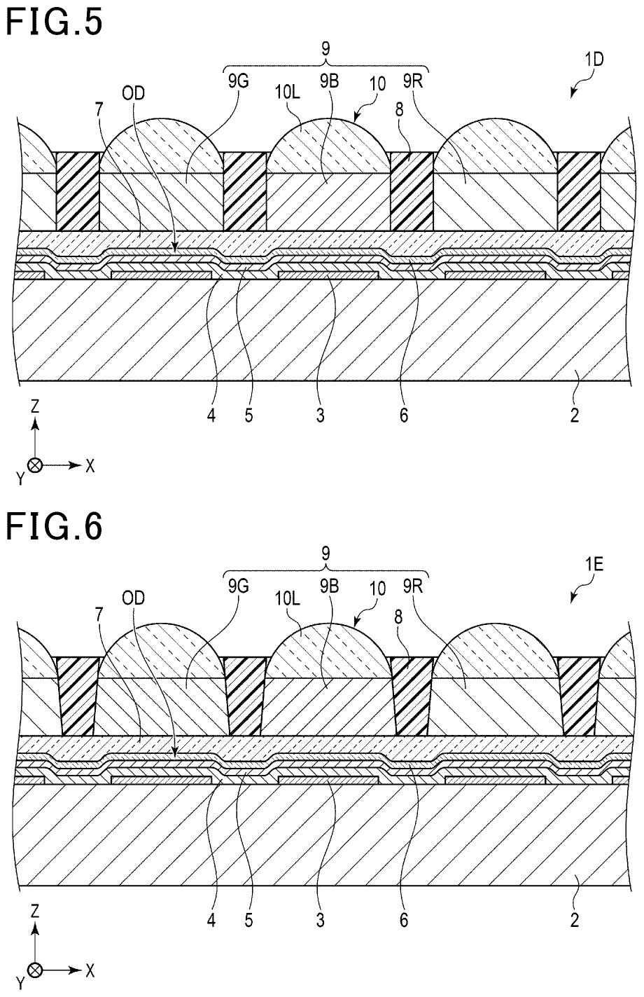

FIG. 6 is a schematic cross-sectional view of a display device according to an embodiment of the present invention. A display device 1E shown in FIG. 6 is the same as the display device ID described with reference to FIG. 5, except that the black matrix 8 has the following structure. That is, in the display device ID, each of the partition portions of the black matrix 8 has a rectangular cross section parallel to the thickness direction of the substrate 2 and the arrangement direction of the colored portions sandwiching the corresponding one of the partition portions. On the other hand, in the display device 1E, each of the partition portions of the black matrix 8 includes a reverse tapered portion having a reverse tapered cross section parallel to the thickness direction of the substrate 2 and the arrangement direction of the colored portions sandwiching the corresponding one of the partition portions.

The cross-sectional shape of the partition portions may vary according to the composition of the black photosensitive resin composition, the exposure conditions, or the like. For example, a black photosensitive resin composition that absorbs a small amount of light used for exposure is used to form a black matrix including partition portions having a rectangular cross section. Furthermore, a black photosensitive resin composition that absorbs a large amount of light used for exposure is used to form a black matrix including partition portions having a reverse tapered cross section.

The display device 1E has the same effects as the display device ID.

The display device 1E may have the following effects.

That is, in the display device 1E, the area of contact between the partition portions and the colored portions is larger than in the display device ID. Therefore, in the display device 1E, the colored portions may be less likely to be peeled off than in the display device 1D.

In the display device 1E in which the black matrix 8 has the structure described with reference to FIG. 6, even when the method in which the lenses 10L are formed by side etching is adopted, and excessive etching causes the lenses 10L to have a diameter smaller than the design value, overhangs of the partition portions may prevent peripheral edge portions of the colored layers from being etched.

In the display device 1E, the height of the top surface of the black matrix 8 may be equal to the height of the top surface of the color filter layer 9. In that case, the display device 1E cannot have the aforementioned effects of the structure in which the height of the top surface of the black matrix 8 is greater than the height of the top surface of the color filter layer 9, but can have other effects.

In the display device 1E, the lens layer 10 may be provided to cover the entire top surface of each of the partition portions of the black matrix 8. In that case, the display device 1E cannot have the aforementioned effects of the structure in which the top surface of each of the partition portions is exposed, but can have other effects.

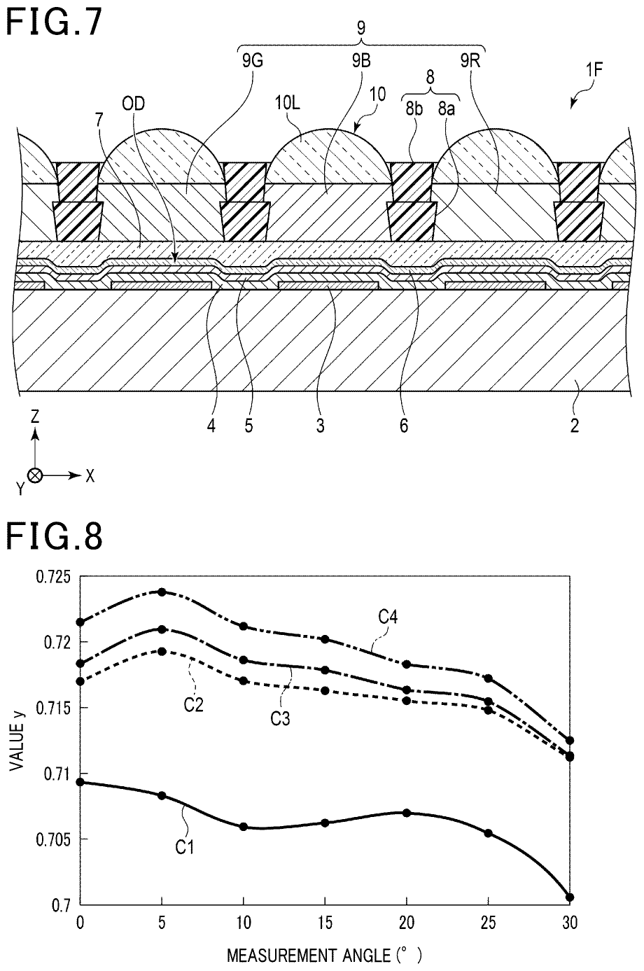

FIG. 7 is a schematic cross-sectional view of a display device according to an embodiment of the present invention. A display device 1F shown in FIG. 7 is the same as the display device 1E described with reference to FIG. 6, except that the black matrix 8 has the following structure. That is, in the display device 1E, the black matrix 8 has a single-layer structure. On the other hand, in the display device 1F, the black matrix 8 has a multilayer structure, in this case, a two-layer structure.

More specifically, in the display device 1F, each of the partition portions of the black matrix 8 includes a plurality of reverse tapered portions laminated in the thickness direction of the substrate 2, in this case, a first reverse tapered portion 8a and a second reverse tapered portion 8b. Each of the first reverse tapered portion 8a and the second reverse tapered portion 8b has a reverse tapered cross section parallel to the thickness direction of the substrate 2 and the arrangement direction of the colored portions. In each of the partition portions, the top surface of one of the plurality of reverse tapered portions located on the upper side has a smaller dimension in the arrangement direction than the top surface of one of the plurality of reverse tapered portions located on the lower side. In this case, the top surface of the second reverse tapered portion 8b has a smaller dimension in the arrangement direction than the top surface of the first reverse tapered portion 8a.

A thick black matrix having a single-layer structure can be formed by performing a single process using a black photosensitive resin composition having high viscosity. A black matrix having a multilayer structure can be obtained by repeatedly performing a plurality of processes to successively form a plurality of layers.

The display device 1F has the same effects as the display device 1E.

The display device 1F may have the following effects.

That is, in the display device 1F, the area of contact between the partition portions and the colored portions is larger than in the display device 1E. Therefore, in the display device 1F, the colored portions may be less likely to become peeled off than in the display device 1E.

In the display device 1F, the top surface of the second reverse tapered portions 8b located on the upper side has a smaller dimension in the arrangement direction than the top surface of the first reverse tapered portions 8a located on the lower side. Therefore, in the display device 1F, the overhanging portions may have less influence on the viewing angle and the light extraction efficiency than in the display device 1E.

In the display device 1F, the height of the top surface of the black matrix 8 may be equal to the height of the top surface of the color filter layer 9. In that case, the display device 1E cannot have the aforementioned effects of the structure in which the height of the top surface of the black matrix 8 is greater than the height of the top surface of the color filter layer 9, but can have other effects.

In the display device 1F, the lens layer 10 may be provided to cover the entire top surface of each of the partition portions of the black matrix 8. In that case, the display device 1F cannot have the aforementioned effects of the structure in which the top surface of each of the partition portions is exposed, but can have other effects.

Furthermore, in the display device 1F, the top surface of the second reverse tapered portions 8b located on the upper side may not necessarily have a smaller dimension in the arrangement direction than the top surface of the first reverse tapered portions 8a located on the lower side. For example, in a display device 1 in which the top surface of the second reverse tapered portions 8b has the same dimension in the arrangement direction as the top surface of the first reverse tapered portions 8a, the overhanging portions may have less influence on the viewing angle and the light extraction efficiency than in the display device 1E. Furthermore, when in a display device, the top surface of the second reverse tapered portions 8b located on the upper side has a larger dimension in the arrangement direction than the top surface of the first reverse tapered portions 8a located on the lower side, the display device may not have the effect in which the overhanging portions have less influence on the viewing angle and the light extraction efficiency, but can have other effects.

The display device described above may be variously modified.

For example, the display device may further include one or more other elements. For example, the display device may further include an overcoat layer, an adhesive layer, and a cover glass.

The overcoat layer is a layer provided on the black matrix 8 and the color filter layer 9. The overcoat layer transmits colored light transmitted through the color filter layer 9. The overcoat layer serves as a planarization layer. The overcoat layer is made of an organic material such as a resin.

The adhesive layer is a layer provided on the overcoat layer. The adhesive layer transmits colored light transmitted through the color filter layer 9 and the overcoat layer. The adhesive layer may be, for example, made of an adhesive.

The cover glass is provided on the adhesive layer. The cover glass transmits colored light transmitted through the color filter layer 9, the overcoat layer, and the adhesive layer. The cover glass protects the organic EL devices, the color filter layer 9, and the like from damage and the like.

In the display device, the organic light emitting layer 4 covers not only the anodes 3 but also the substrate 2 at the positions of the gaps between the substrate 2 and the organic light emitting layer 4. The display device may further include a barrier insulating layer that is interposed between the substrate 2 and the cathode 5 and has through holes at the positions of the anodes 3. In that case, the organic light emitting layer 4 may be provided to cover only the anodes 3. When the display device 1A further includes a barrier insulating layer, the cathode 5 is provided to cover the barrier insulating layer and the organic light emitting layer 4.

The display device described above is an organic EL microdisplay; however, the technique described herein can be applied to other display devices. For example, the display device may be a micro LED display including a light-emitting diode as a light-emitting element.

Tests performed in relation to the present invention will be described.

A display device was produced in the same manner as the display device 1X described above, except that a Bayer arrangement was adopted instead of the stripe arrangement and the black matrix 8 was omitted. The thickness of the color filter layer 9 was 1.2 μm, and the dimensions of the colored portions in the X direction and the Y direction were 3.0 μm. Hereinafter, this display device is referred to as sample S1.

A display device was produced in the same manner as the display device 1X described above, except that a Bayer arrangement was adopted instead of the stripe arrangement. The black matrix 8 had a thickness of 1.0 μm, and included partition portions having a rectangular cross section with a width of 0.7 μm. The other dimensions of the display device were the same as those of the sample S1. Hereinafter, this display device is referred to as sample S2.

A display device was produced in the same manner as the display device 1A described above, except that the Bayer arrangement was adopted instead of the stripe arrangement. The black matrix 8 had a thickness of 1.2 μm, and included partition portions having a rectangular cross section with a width of 0.7 μm. The thickness of the color filter layer 9 was 1.2 μm, and the dimensions of the colored portions in the X direction and the Y direction were 4.0 μm. Hereinafter, this display device is referred to as sample S3.

A display device was produced in the same manner as the display device 1B described above, except that a Bayer arrangement was adopted instead of the stripe arrangement. The black matrix 8 had a thickness of 1.4 μm, and included partition portions having a rectangular cross section with a width of 0.7 μm. The thickness of the color filter layer 9 was 1.2 μm, and the dimensions of the colored portions in the X direction and the Y direction were 4.0 μm. Hereinafter, this display device is referred to as sample S4.

In each of the samples S1 to S4, only green subpixels were turned on, and the viewing angle dependence of the chromaticity value y of the CIE color system was examined. The results are shown in FIG. 8.

In FIG. 8, curves C1, C2, C3, and C4 indicate the results obtained for the samples S1, S2, S3, and S4, respectively.

The values y of the curves C2 to C4 were higher than the value y of the curve C1 in the entire measurement angle range. For green, a higher value y indicates higher color saturation. Therefore, samples S2 to S4 prevented color mixing, unlike sample S1.

The values y of the curves C3 and C4 were higher than the value y of the curve C2 in the entire measurement angle range. That is, samples S3 and S4 had a better color mixing prevention effect than sample S2.

The value y of the curve C4 was higher than the value y of the curve C3 in the entire measurement angle range. That is, sample S4 had a better color mixing prevention effect than sample S3.

The present invention provides a technique useful to achieve a display device having good viewing angle characteristics.

Obviously, numerous modifications and variations of the present invention are possible in light of the above teachings. It is therefore to be understood that within the scope of the appended claims, the invention may be practiced otherwise than as specifically described herein.

1. A display device comprising:
a substrate;
a plurality of light-emitting elements that are provided on the substrate;
a color filter layer that is provided on the plurality of light-emitting elements and includes a plurality of colored portions facing the respective plurality of light-emitting elements; and
a black matrix that includes a plurality of partition portions, each of the partition portions being sandwiched between adjacent ones of the plurality of colored portions, wherein
a height of a top surface of the black matrix is equal to or greater than a height of a top surface of the color filter layer.

2. The display device according to claim 1, wherein the height of the top surface of the black matrix is greater than the height of the top surface of the color filter layer.

3. The display device according to claim 1, further comprising a lens layer that is provided on the color filter layer and includes a plurality of lenses facing the respective plurality of colored portions.

4. The display device according to claim 1, further comprising a lens layer that is provided on the color filter layer and includes a plurality of lenses facing the respective plurality of colored portions, wherein
the height of the top surface of the black matrix is greater than the height of the top surface of the color filter layer, and
the lens layer has openings at positions of the plurality of partition portions so that a top surface of each of the plurality of partition portions is at least partially exposed.

5. The display device according to claim 3, wherein the lens layer comprises an inorganic compound or a cured product of a non-photosensitive resin.

6. The display device according to claim 1, wherein each of the plurality of partition portions includes a reverse tapered portion having a reverse tapered cross section parallel to a thickness direction of the substrate and parallel to an arrangement direction of the colored portions sandwiching the corresponding one of the plurality of partition portions.

7. The display device according to of claim 1, wherein each of the plurality of partition portions includes a plurality of reverse tapered portions that are laminated in a thickness direction of the substrate and have a reverse tapered cross section parallel to the thickness direction and parallel to an arrangement direction of the colored portions sandwiching the corresponding one of the plurality of partition portions.

8. The display device according to claim 7, wherein in each of the plurality of partition portions, a top surface of one of the plurality of reverse tapered portions located on an upper side of the partition portion has a smaller dimension in the arrangement direction than a top surface of at least one of the plurality of reverse tapered portions located on a lower side of the partition portion.

9. The display device according to claim 1, wherein the black matrix is comprised of a cured product of a black photosensitive resin composition.

10. The display device according to claim 1, wherein each of the plurality of light-emitting elements comprises an organic electroluminescent device.

11. A method of forming a lens layer on a display device having a black matrix and a color filter layer, the color filter layer having a plurality of colored portions, the method comprising:
forming a coating film layer comprising a photosensitive resin over the black matrix and the color filter layer;
pattern exposing the coating film layer;
developing the coating film layer to form a plurality of columnar bodies located on a center portion of each of the plurality of colored portions; and
reflow soldering the columnal bodies to form the lens layer.

12. The method of claim 11, wherein the pattern exposing pattern exposes the coating film layer via a gray-toned mask configured such that an amount of exposure is successively increased from a portion of the coating film that corresponds to a center of a through hole of the black matrix towards a portion of the coating film that corresponds to a side wall of through hole.

13. The method of claim 12, wherein an amount of exposure is largest at portions of the coating film layer located directly above partition portions of the black matrix.

14. The method of claim 11, wherein
the photosensitive resin comprises a negative photosensitive resin,
a free surface energy of the black matrix is different from a free surface energy of each of the plurality of colored portions, and
a surface tension of the negative photosensitive resin is approximately equal to the surface free energy of the plurality of colored portions.

15. The method of claim 14, wherein the surface tension of the negative photosensitive resin is different from the surface free energy of the black matrix.

16. A method of forming a lens layer on a display device having a black matrix, a color filter layer, and a transparent material layer, the color filter layer having a plurality of colored portions and the transparent material layer covering the plurality of colored portions, the method comprising:
forming on the transparent material layer, with photolithography and a thermal reflow process, a lens matrix having an island pattern corresponding to center portions of the lens layer; and
dry etching the transparent material layer to form the lens layer.

17. The method of claim 16, wherein the thermal reflow process uses a resist material having alkali soluble property, photosensitivity, and thermal flow properties.

18. The method of claim 17, wherein the transparent material layer does not comprise a photosensitive material.

19. The method of claim 17, wherein the lens layer comprises an inorganic compound.

20. The method of claim 17, wherein the lens layer comprises a cured product of a non-photosensitive resin.
